(19) United States
(12) Patent Application Publication
(10) Pub. No.: US 2006/0105569 A1
(43) Pub. Date: May 18, 2006

(54) Method for manufacturing semiconductor device

(75) Inventor: Hyung Hwan Kim, Gyeonggi-do (KR)

Correspondence Address: HELLER EHRMAN WHITE & MCAULIFFE LLP, 1717 RHODE ISLAND AVE, NW, WASHINGTON, DC, 20036-3001, US

(73) Assignee: Hynix Semiconductor Inc., Gyeonggi-do (KR)

(21) Appl. No.: 11/148,563

(22) Filed: Jun. 9, 2005

(30) Foreign Application Priority Data
Nov. 15, 2004 (KR) 10-2004-0093223

(51) Int. Cl. H01L 21/44; H01L 21/461

(52) U.S. Cl. 438/675; 438/692

(57) ABSTRACT

A method for manufacturing a semiconductor device is disclosed. The method for manufacturing a semiconductor device provides performing the CMP process using the acid slurry for metal during formation of the landing plug to minimize the step difference.

### BACKGROUND OF THE INVENTION

1. Field of the Invention

The present invention generally relates to a method for manufacturing a semiconductor device, and more specifically, to a method for manufacturing a semiconductor device wherein an acid slurry for metal is used in the CMP process during the formation process of the landing plug to minimize a process time and stabilize the process, thereby improving yield of the semiconductor device.

2. Description of the Related Art

FIGS. 1a through 1j are plane views and cross-sectional views illustrating a conventional method for manufacturing a semiconductor device, wherein FIGS. 1b through 1d are cross-sectional views taken along the line A-A′ of FIG. 1a, and FIGS. 1f through 1j are cross-sectional views taken along the line B-B′ of FIG. 1e.

FIG. 1a is a plane view illustrating a gate 20 prior to formation of a landing plug contact (“LPC”).

Referring to FIG. 1b, a gate 20 having a stacked structure of a gate conductive layer 35 and a hard mask nitride film 15 is formed on a gate insulating film 30 disposed on a semiconductor substrate 10. Thereafter, an etch stop nitride film 40 is formed on the semiconductor substrate 10 between the gates 20. An interlayer insulating film 25 is then deposited on the entire surface to fill up the gates 20.

Referring to FIG. 1c, the interlayer insulating film 25 is subjected to a CMP process until the hard mask nitride film 15 is exposed.

Referring to FIG. 1d, a LPC hard mask layer 45 is formed on the hard mask nitride film 15 and the interlayer insulating film 25.

Referring to FIGS. 1e and 1f, a predetermined region of the LPC hard mask layer 45 is removed to form a LPC hard mask layer pattern 70 defining a landing plug contact region.

Next, the interlayer insulating film 25 is etched using the LPC hard mask layer pattern 70 as an etching mask to expose the etch stop nitride film 40.

Thereafter, a buffer oxide film 50 is formed on the entire surface.

A predetermined region of the buffer oxide film 50, the etch stop nitride film 40 and the gate oxide film 30 is then etched until the semiconductor substrate 10 of the landing plug contact region is exposed to form a LPC hole 65.

Referring to FIG. 1g, a polysilicon layer 55 is deposited to fill up the LPC hole 65.

Referring to FIG. 1h, the polysilicon layer 55 is subjected to a CMP process to form a landing plug.

Referring to FIG. 1i, a second interlayer insulating film 60 is formed on the landing plug and the hard mask nitride film 15.

Referring to FIG. 1j, the second interlayer insulating film 60 is subjected to a CMP process to remove a step difference.

The subsequent process may include known semiconductor fabrication processes.

FIG. 2 is a photograph illustrating the step difference occurring in a cell region and the peripheral circuit region after formation of the landing plug according to the conventional method for manufacturing a semiconductor device.

In accordance with the above-described conventional method for manufacturing a semiconductor device, the step difference occurs due to the difference between the etch rate of a hard mask nitride film and that of an interlayer oxide film. That is, the oxide film is etched faster than the nitride film during the CMP process. The step difference causes a problem such as a disconnected bit line in a subsequent process for forming a bit line pattern.

On the other hand, a method to solve the above problem needs to have an additional CMP process to remove the step difference. However, the method causes increase in process cost and process time because of the additional CMP process.

### SUMMARY OF THE INVENTION

Accordingly, it is an object of the present invention to provide a method for manufacturing a semiconductor device wherein an acid slurry for metal is used in the CMP process during the formation process of the landing plug to minimize a process time and stabilize the process, thereby improving yield of the semiconductor device.

In order to achieve the above object of the present invention, there is provided a method for manufacturing a semiconductor device comprising the steps:

(a) forming an interlayer insulating film on a gate disposed on a semiconductor substrate, the gate comprising a stacked structure of a gate conductive layer and a hard mask nitride film,

(b) subjecting the interlayer insulating film to a CMP process using a high selectivity slurry to expose the hard mask nitride film,

(c) forming an LPC hard mask layer pattern exposing a landing plug contact region on the hard mask nitride film and the interlayer insulating film,

(d) etching the interlayer insulting film using the LPC hard mask layer pattern as an etching mask to form a LPC hole,

(e) depositing a polysilicon layer filling up the LPC hole, and

(f) performing a CMP process using an acid slurry for metal until the hard mask nitride film is exposed to form a landing plug.

### BRIEF DESCRIPTION OF THE DRAWINGS

FIGS. 1a through 1j are plane views and cross-sectional views illustrating a conventional method for manufacturing a semiconductor device.

FIG. 2 is a photograph illustrating the step difference according to a conventional method for manufacturing a semiconductor device.

FIGS. 3a through 3i are plane views and cross-sectional views illustrating a method for manufacturing a semiconductor device according to a preferred embodiment of the present invention.

FIG. 4 is a photograph illustrating the step difference according to a preferred embodiment of the present invention.

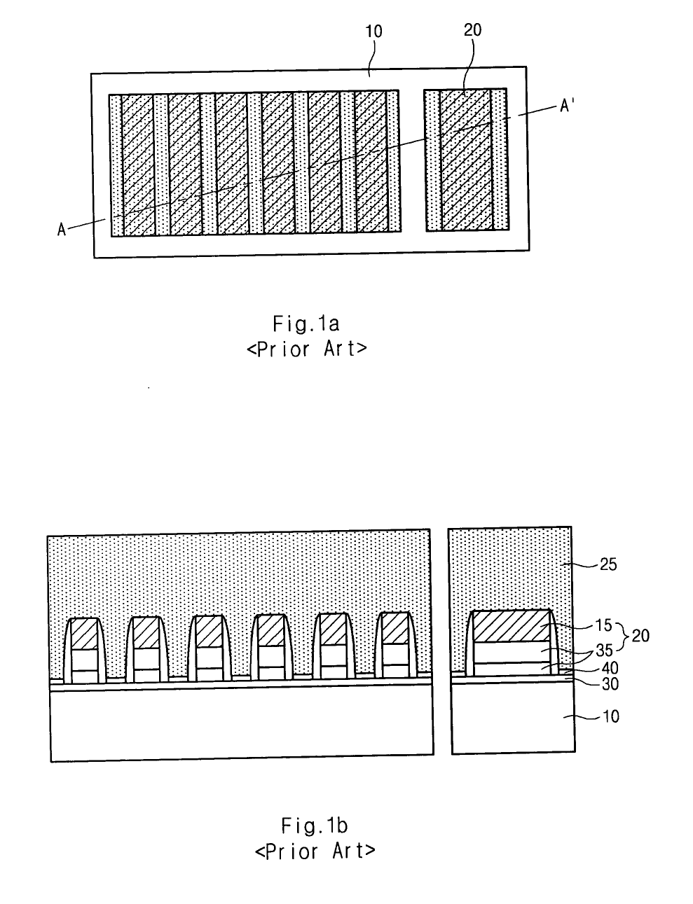

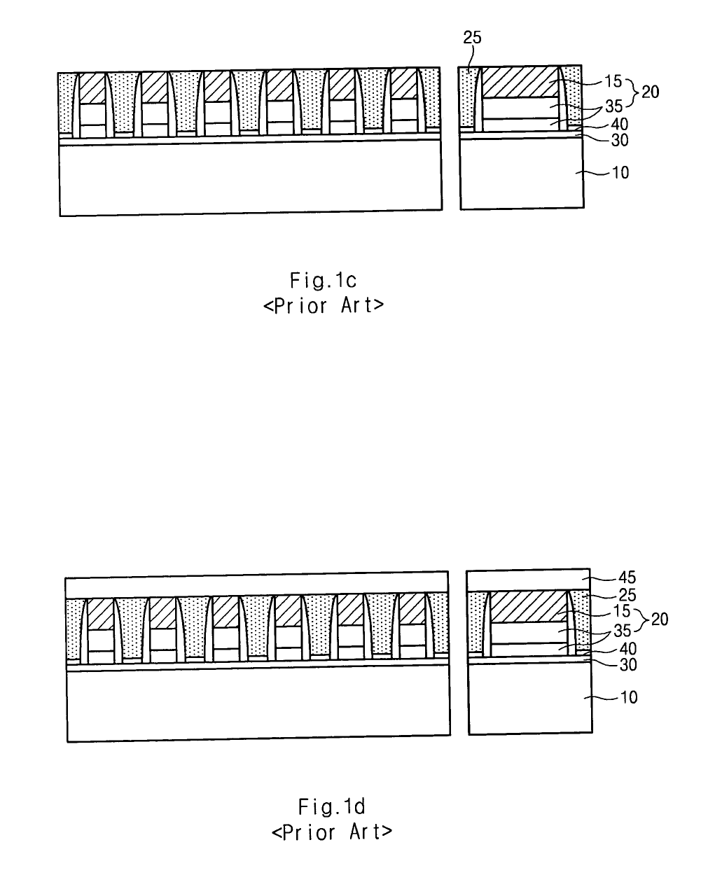

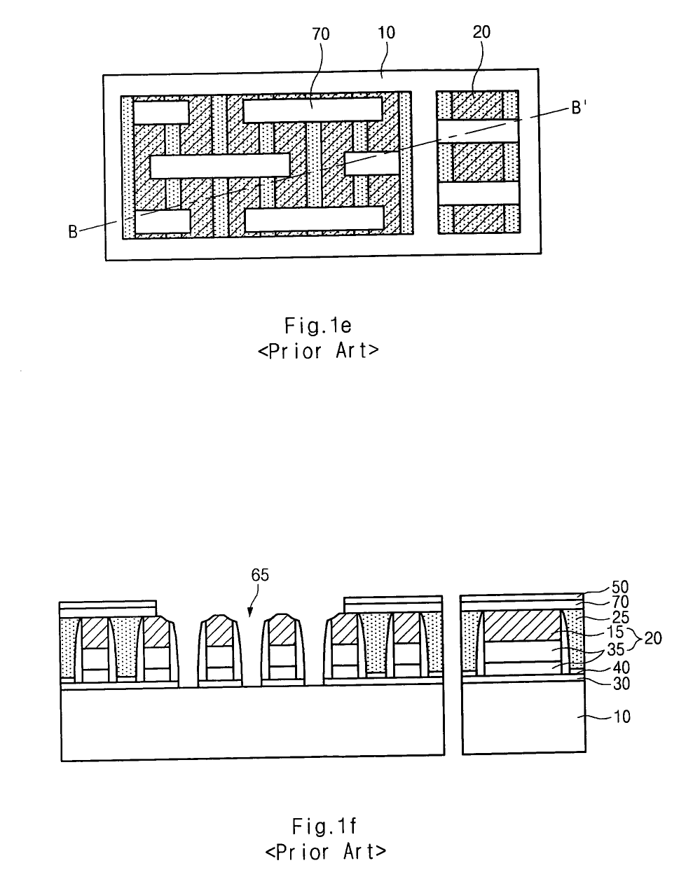

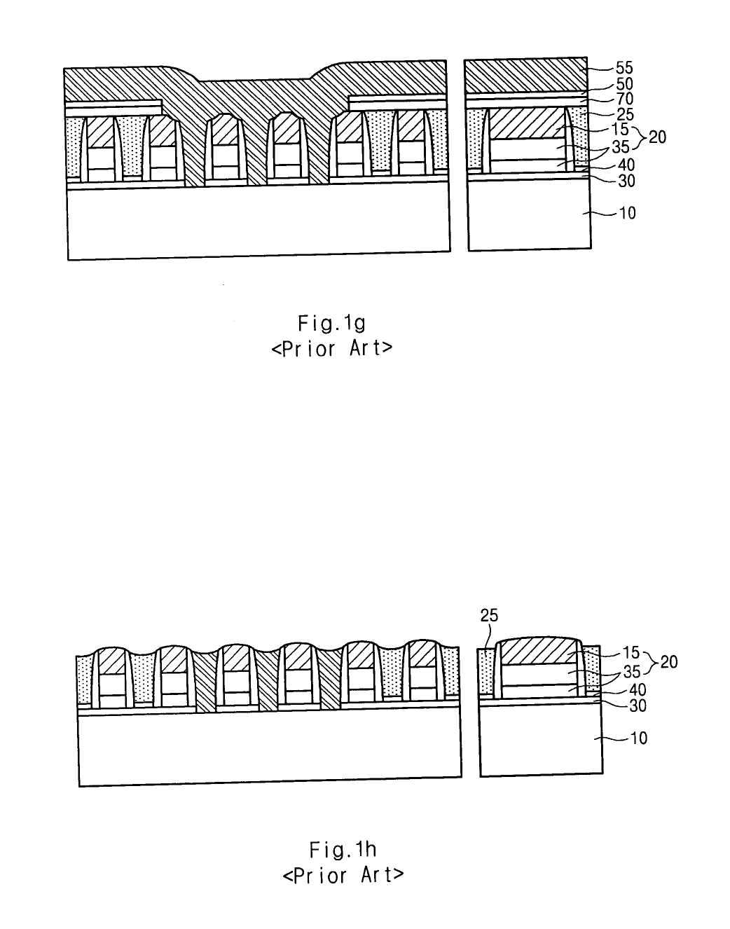

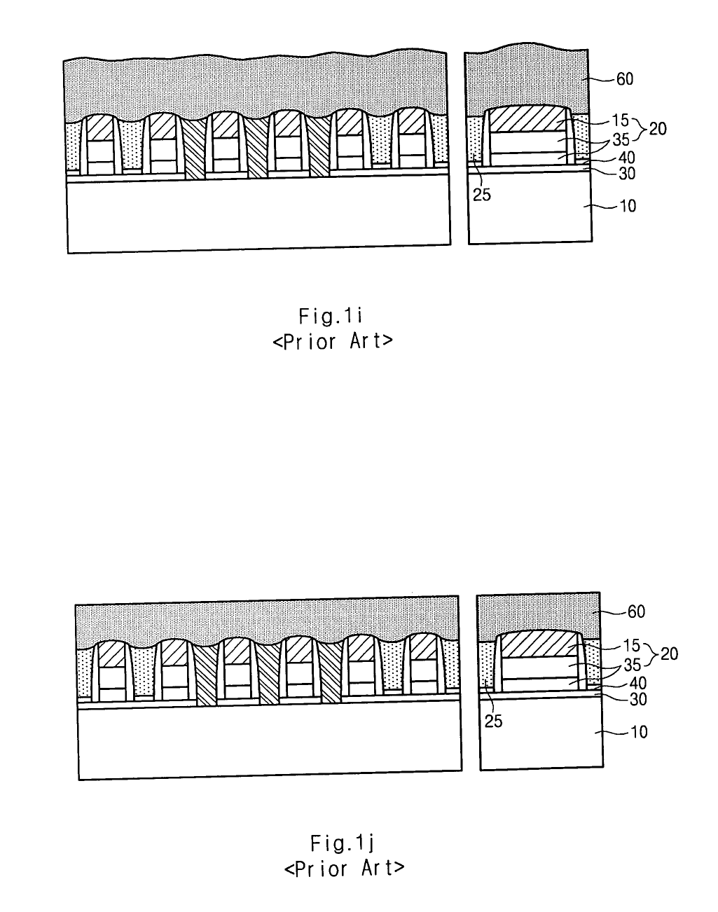

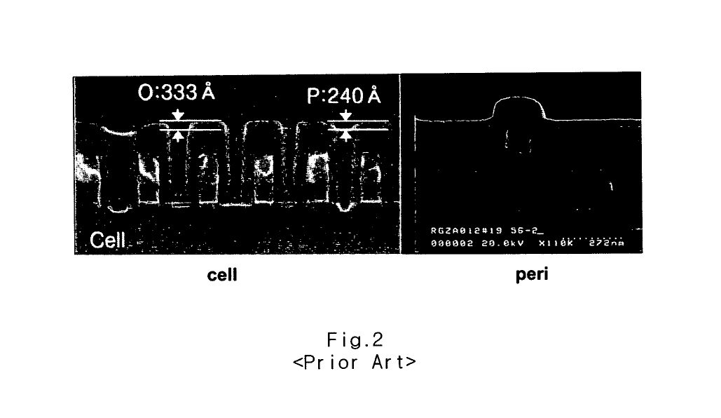

### DETAILED DESCRIPTION OF THE PREFERRED EMBODIMENTS

Reference will now be made in detail to exemplary embodiments of the present invention. Wherever possible, the same reference numbers will be used throughout the drawings to refer to the same or like parts.

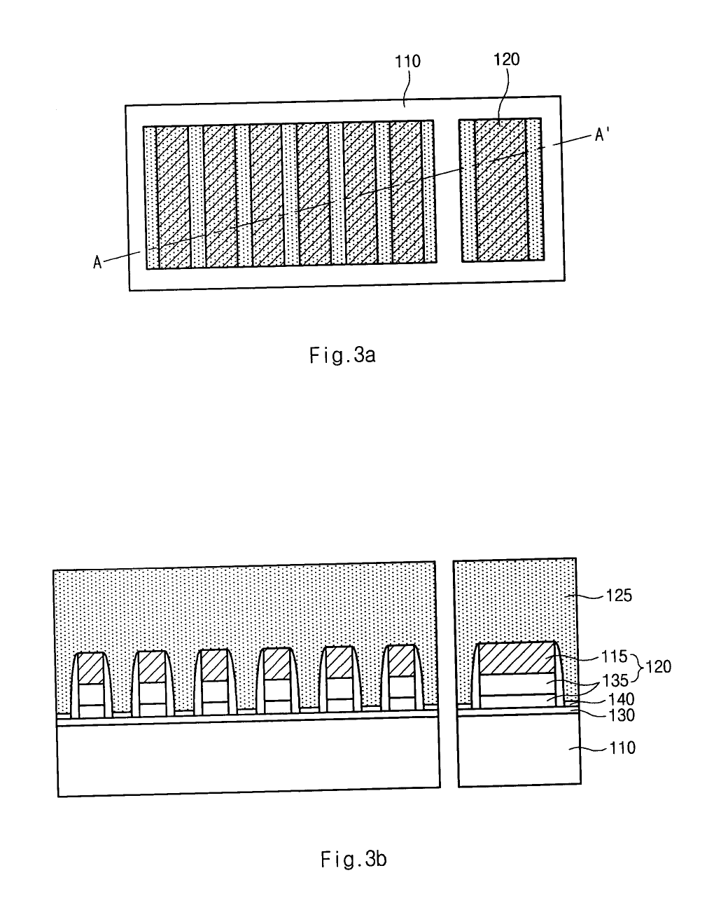

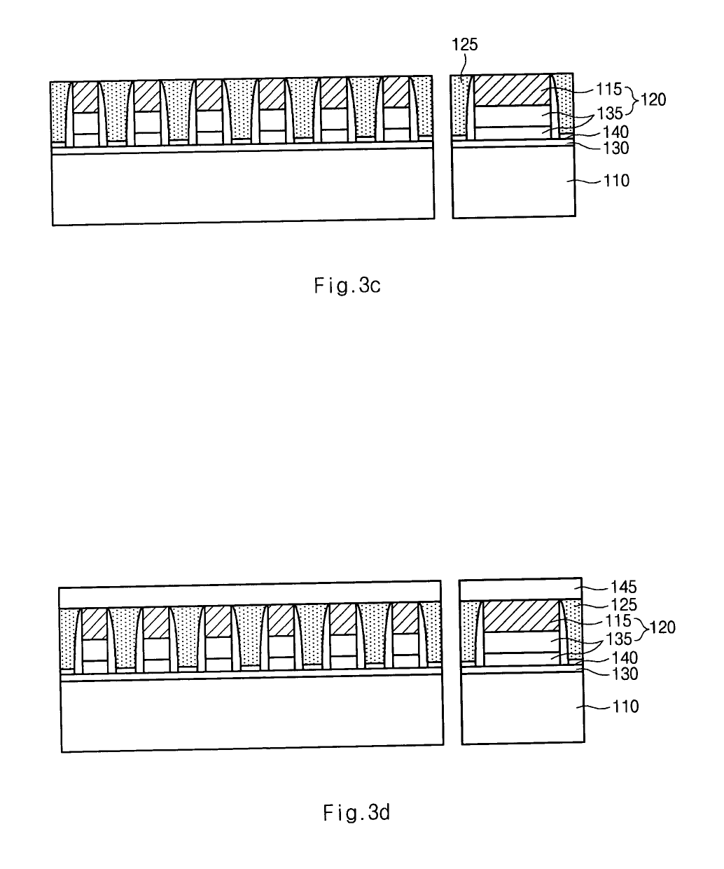

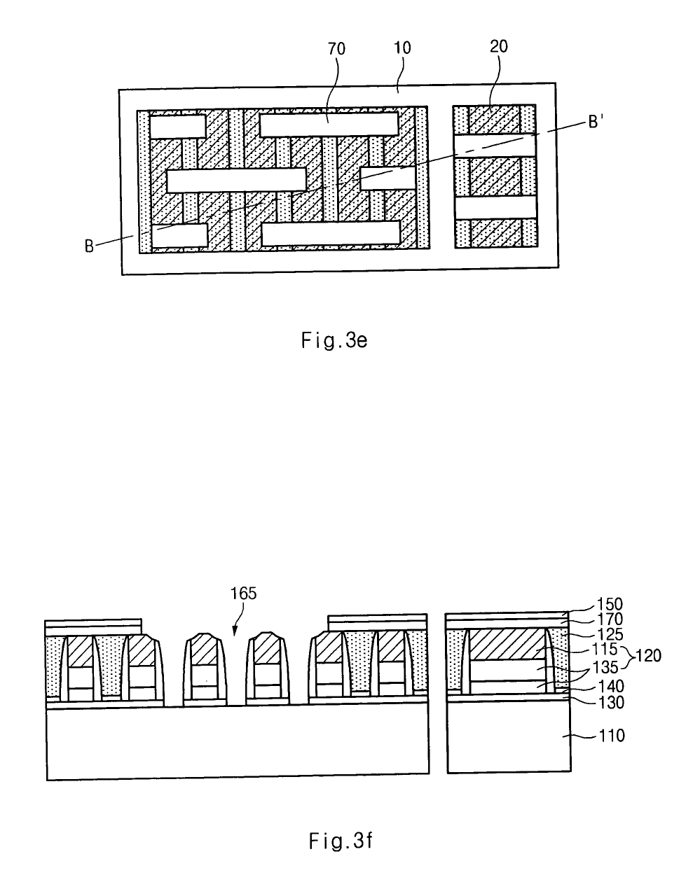

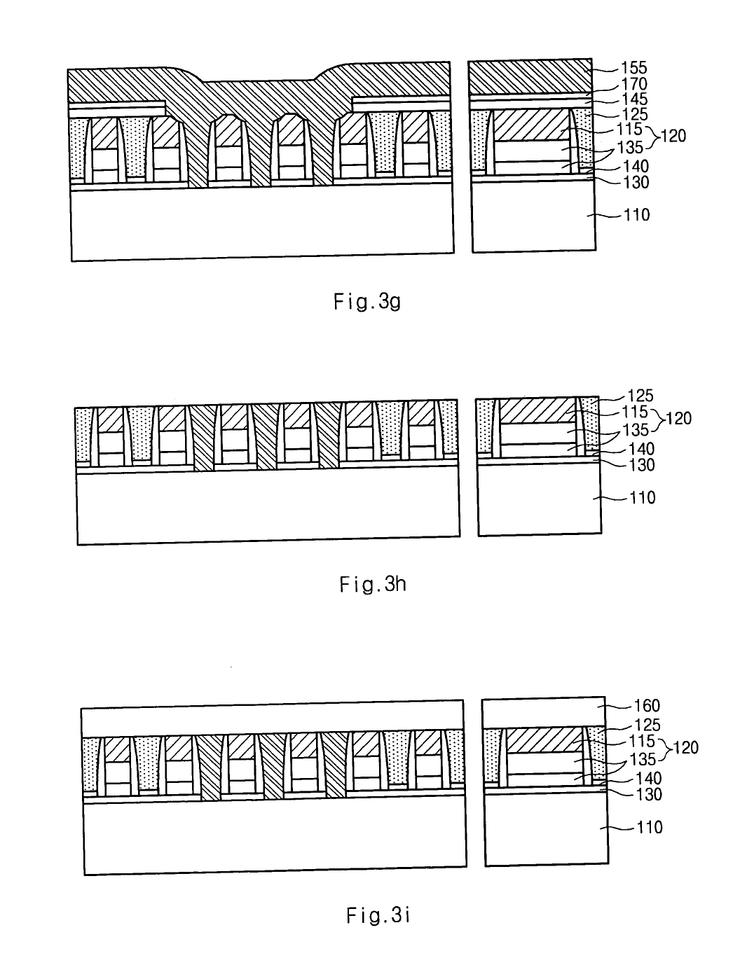

FIGS. 3a through 3i are plane views and cross-sectional views illustrating a method for manufacturing a semiconductor device according to a preferred embodiment of the present invention, wherein FIGS. 3b through 3d are cross-sectional views taken along the line A-A′ of FIG. 3a, and FIGS. 3f through 3i are cross-sectional views taken along the line B-B′ of FIG. 3e.

FIG. 3a is a plane view illustrating a gate prior to formation of a landing plug contact.

Referring to FIG. 3b and FIG. 3c, a gate 120 having a stacked structure 120 of a gate conductive layer 135 and a hard mask nitride film 115 is formed on a gate insulating film 130 disposed on a semiconductor substrate 110. Thereafter, an etch stop nitride film 140 is formed on the semiconductor substrate 110 between the gates 120.

Next, an interlayer insulating film 125 is formed on the entire surface of the semiconductor substrate 110 to at least fill up a space between the gates 120. The interlayer insulating film 125 is then subjected to a CMP process using high selectivity slurry until the hard mask nitride film 115 is exposed.

The high selectivity slurry has an etching selectivity ratio of the hard mask nitride film to the interlayer insulating film ranging from 1:10 to 1:200 during the CMP process.

Preferably, a pH of the high selectivity slurry ranges from 2 to 12, and an abrasive of the high selectivity slurry is selected from SiO₂, CeO₂, Al₂O₃, Zr₂O₃ or combinations thereof.

Moreover, the abrasive of the high selectivity slurry is preferably formed via a fumed method or a colloidal method.

Referring to FIG. 3d, a LPC hard mask layer 145 is formed on the hard mask nitride film 115 and the interlayer insulating film 125.

Here, the LPC hard mask layer 145 comprises a polysilicon layer or a nitride film, and a thickness of the LPC hard mask layer 145 ranges from 300 Å to 5000 Å, preferably.

Referring to FIGS. 3e and 3f, a LPC hard mask layer pattern 170 exposing a landing plug contact region is formed on the hard mask nitride film 115 and the interlayer insulating film 125.

Next, the interlayer insulating film 125 is etched using the hard mask layer pattern 170 as an etching mask to expose the etch stop nitride film 140.

Thereafter, a thin USG buffer oxide film 150 is formed on the entire surface. Preferably, in order to prevent damage of a landing plug in the subsequent etching process, the thickness of a portion of the USG buffer oxide film 150 formed on a sidewall of the gate 120 is smaller than that of a portion of the USG buffer oxide film 150 formed on the LPC hard mask layer pattern 170 and the etch stop nitride film 140.

Referring to FIG. 3g, a polysilicon layer 155 filling up the LPC hole 165 is deposited.

Referring to FIG. 3h, a CMP process is performed using acid slurry for metal until the hard mask nitride film 115 is exposed to form the landing plug.

The etching rates of the hard mask nitride film 115, the interlayer insulating film 125 and a polysilicon layer 155 preferably range from 100 Å/min to 500 Å/min during the CMP process.

Moreover, an etch selectivity ratio of the hard mask nitride film 125, an oxide film for the interlayer insulating film 125 and the polysilicon layer 155 ranges from 1:1:1 to 1:1:4, respectively.

On the other hand, a pH of the acid slurry for metal preferably ranges from 2 to 8.

Preferably, an abrasive of the acid slurry for metal is selected from SiO₂, CeO₂, Al₂O₃, Zr₂O₃ or combinations thereof. The abrasive may be formed via a fumed method or a colloidal method.

Referring to FIG. 3i, a second interlayer insulating film 160 is formed on the landing plug and the hard mask nitride film 115 after formation of the LPC. Preferably, a thickness of the second interlayer insulating film 160 ranges from 500 Å to 3000 Å.

The subsequent process may include known semiconductor fabrication processes.

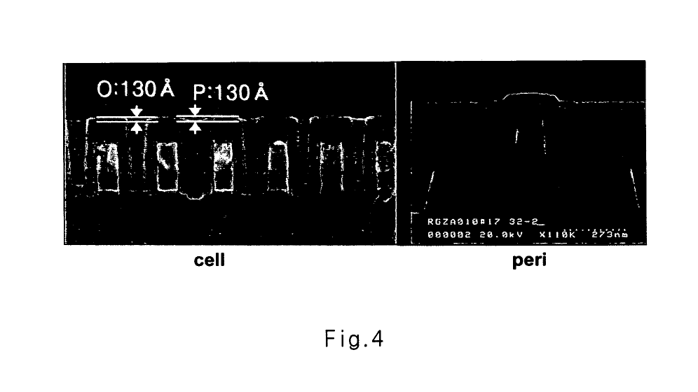

FIG. 4 is a photograph illustrating a step difference occurring in a cell region and a peripheral circuit region after the formation process of the landing plug according to a preferred embodiment of the present invention.

Referring to FIG. 4, it shows the improved step difference in the peripheral circuit region in accordance with the CMP process using the acid slurry for metal of the present invention compared to the conventional method.

As described above, the method for manufacturing a semiconductor device in accordance with the preferred embodiment of the present invention provides improved time and cost of the fabrication process of a semiconductor device wherein an acid slurry for metal is used in the CMP process during the formation process of the landing plug.

As the present invention may be embodied in several forms without departing from the spirit or essential characteristics thereof, it should also be understood that the above-described embodiment is not limited by any of the details of the foregoing description, unless otherwise specified, but rather should be construed broadly within its spirit and scope as defined in the appended claims, and therefore all changes and modifications that fall within the metes and bounds of the claims, or equivalences of such metes and bounds are therefore intended to be embraced by the appended claims.

1. A method for fabricating a semiconductor device, comprising the steps of:
(a) forming an interlayer insulating film on a gate disposed on a semiconductor substrate, the gate comprising a stacked structure of a gate conductive layer and a hard mask nitride film;
(b) subjecting the interlayer insulating film to a CMP process using a high selectivity slurry to expose the hard mask nitride film;
(c) forming an LPC hard mask layer pattern exposing a landing plug contact region on the hard mask nitride film and the interlayer insulating film;
(d) etching the interlayer insulting insulating film using the LPC hard mask layer pattern as an etching mask to form a LPC hole;
(e) depositing a polysilicon layer filling up the LPC hole; and
(f) performing a CMP process using an acid slurry for metal until the hard mask nitride film is exposed to form a landing plug, wherein an etch selectivity ratio of the hard mask nitride film, an oxide film for the interlayer insulating film and the polysilicon layer of the CMP process ranges from 1:1:1 to 1:1:4, respectively.

2. The method according to claim 1, wherein an etching selectivity ratio of the hard mask nitride film to the interlayer insulating film ranges from 1:10 to 1:200 during the CMP process of the step (b).

3. The method according to claim 1, wherein a pH of the high selectivity slurry used during the CMP process of the step (b) ranges from 2 to 12.

4. The method according to claim 1, wherein an abrasive of the high selectivity slurry used during the C<P process of the step (b) ranges from 2 to 12.

5. The method according to claim 4, wherein the abrasive is formed via a fumed method or a colloid method.

6. The method according to claim 1, wherein the LPC hard mask layer pattern comprises a polysilicon layer or a nitride film.

7. The method according to claim 1, wherein a thickness of the LPC hard mask layer pattern ranges from 300 Å to 5,000 Å.

8. The method according to claim 1, wherein etch rates of the hard mask nitride film, the interlayer insulating film and the polysilicon layer range from 100 Å/min to 500 Å/min during the CMP process of step (f).

9. (canceled)

10. The method according to claim 1, wherein a pH of the slurry used during the CMP process of the step (f) ranges from 2 to 8.

11. The method according to claim 1, wherein an abrasive of the slurry used during the CMP process of the step (f) is selected from the group consisting of SiO₂, CeO₂, Al₂O₃, Zr₂O₃ and combinations thereof.

12. The method according to claim 11, wherein the abrasive is formed via a fumed method or a colloid method.

13. The method according to claim 1, further comprising forming a second interlayer insulating film having a thickness ranging from 500 Å to 3000 Å on the landing plug and the hard mask layer pattern.
